(19) United States
(12) Patent Application Publication
(10) Pub. No.: US 2023/0285911 A1
(43) Pub. Date: Sep. 14, 2023

(54) FACILITY AND METHOD FOR DISTRIBUTING A GAS MIXTURE FOR DOPING SILICON WAFERS

(71) Applicant: Air Liquide Electronic Systems, Paris (FR)

(72) Inventors: Vanina TODOROVA, Crolles (FR); Herve DULPHY, Jarrie (FR)

(21) Appl. No.: 18/008,375

(22) PCT Filed: May 27, 2021
(86) PCT No.: PCT/EP2021/064250

§ 371 Date: Dec. 5, 2022

(30) Foreign Application Priority Data
Jun. 5, 2020 (FR) FR2005923

(51) Int. Cl. B01F 23/10; B01F 35/221; B01F 35/21; B01F 35/22; B01F 35/83

(52) U.S. Cl. CPC B01F 23/191; B01F 35/2211; B01F 35/2111; B01F 35/2202; B01F 35/2132; B01F 35/83; B01F 2101/58

(57) ABSTRACT

Plant for delivering a gas mixture to a silicon wafer doping unit comprising a source of a dopant gas (1), a source of a carrier gas (2), a mixer device (3) connected to the container of dopant gas (1) and to the source of carrier gas (2), a first flow regulator member (41) and a second flow regulator member (42) for regulating the flows of the dopant gas (1) and of the carrier gas (2) towards the mixer device (3), a control unit (5) for controlling the first and second flow regulator members (41, 42) so as to adjust the first flow rate setpoint (D1) and the second flow rate setpoint (D2) in proportions determined as a function of at least one target content (C1, C2) of dopant gas (1) and/or carrier gas (2) in the mixture, a buffer tank (7), a delivery line (6) for delivering the mixture to a doping unit (10) with a consumption flow rate (DC), at least one measurement sensor (8) for measuring a physical quantity, the variation of which is representative of a variation in the consumption flow rate (DC) and for providing a first measurement signal, the control unit (5) being connected to the sensor (8) and configured to produce a first control signal from the first measurement signal, the flow regulator members (41, 42) being configured to adjust the first and second flow rate setpoints (D1, D2) in response to said first control signal.

### CROSS REFERENCE TO RELATED APPLICATIONS

This application is a 371 of International Application No. PCT/EP2021/064250, filed May 27, 2021, which claims priority to French Patent Application No. 2005923, filed Jun. 5, 2020, the entire contents of which are incorporated herein by reference.

### TECHNICAL FIELD

The present invention relates to a plant for delivering a gas mixture intended to be used by a unit for doping silicon wafers. The plant enables the mixture to be delivered directly to the site of use and also an adjustment of the flow rate of mixture produced by the plant as a function of the flow consumed by the consuming unit. The invention also relates to an assembly for doping silicon wafers comprising such a plant.

In particular, a plant and a process according to the invention are intended to deliver mixtures of pure gas mixtures or gas pre-mixtures, in particular to deliver mixtures of so-called carrier gases and of so-called dopant gases.

Note that the expression “doping unit” may extend both to a single doping unit and to several entities supplied in parallel by the gas mixture, in particular several entities arranged downstream of a branch box.

The present invention applies in particular to the doping of silicon wafers in the semiconductor production process.

### BACKGROUND

In the process for fabricating integrated circuits for electronics, the technologies for fabricating semiconductors are based mainly on the intrinsic modification of the matrix comprising the silicon atoms by inserting therein so-called doping elements, in order to make the silicon seMiconductive. Known doping elements are, for example, germanium, phosphorus, arsenic, antimony, boron, gallium, aluminium.

In the most commonly used doping processes, with phosphorus or boron for example, the silicon wafers are introduced into a furnace and brought to a temperature generally between 800° C. and 1200° C., Mixtures of dopant gases and of carrier gases are introduced into the chamber of the furnace. The carrier gas has the role of transporting the dopant gas to the surface of the silicon wafer.

Usually, the gas mixtures are packaged in compressed or liquefied form in gas cylinders. The filling of a gas cylinder is carried out in sequential mode, the constituents of the mixture being introduced one after the other into the cylinder. For each constituent, a check on the amount of gas introduced into the cylinder is carried out, either by monitoring the pressure in the cylinder during and after the introduction of the constituent, or by weighing the cylinder during the introduction of the constituent. Such a plant for packaging gas mixtures is in particular described in document WO 2010/031940 A1.

In order to guarantee to the user the reliability and the reproducibility of the performance and/or results provided by the gas-consuming unit, it is necessary to produce gas mixtures that offer great precision over the concentrations of each constituent. Depending on the applications, the maximum tolerance for variation of the actual values of the concentrations relative to the target values may be less than 1% (relative %), or less than 0.5% or even less than 0.1%. The greater the number of constituents and/or the lower the contents thereof, the more difficult it is to meet such tolerances.

This is the case in particular with dopant mixtures for the fabrication of integrated circuits which involve flow rates of mixtures and contents of dopant gases that are relatively low. This necessitates further improving the monitoring of the contents of dopant gases and ensuring the accuracy and stability thereof, which monitoring proves even more critical owing to the nature of the dopant gases, the constituents of which are potentially flammable, pyrophoric and/or toxic.

Depending on the required accuracy, the current packaging methods may prove insufficient. In particular, the manometric packaging by control of the pressure offers an accuracy that is intrinsically limited by the accuracy of the pressure sensor and by the variations in temperature which influences the calculation of the amount of gas. Added to the uncertainty regarding the concentration values of the gas mixture produced are the differences in concentration between the mixtures packaged in different cylinders. Such differences may cause the results produced by the consuming unit to vary substantially on each cylinder change.

Gravimetric packaging by weighing the constituents offers greater accuracy regarding the composition of the mixture but still requires a stepwise process with filling of cylinders.

However the use of cylinders results in a limited autonomy for the user with a stoppage of the delivery that is difficult to predict when the consumption of the gas mixture varies. Since the lead times of the gas mixtures may be relatively long, the user must manage their stock of cylinders in order to ensure continuity of their production.

Furthermore, the filling of cylinders with the mixtures takes place in packaging centres specifically equipped for operations of this type. The cylinders must then be transported to their site of use, which requires dedicated logistics. Constraints linked to the transportation of dangerous goods are also present when it is a question of transporting mixtures of gases containing flammable, pyrophoric, toxic and/or anoxic constituents.

Furthermore, the operations of connecting/deconnecting the cylinders are tedious for the users and increase the risk of contaminating the gas mixture with ambient air. The cylinders also require a specific preparation before filling including steps of cleaning, passivating, etc.

### SUMMARY

The objective of the invention is to overcome all or some of the drawbacks mentioned above, in particular by proposing a plant for delivering a gas mixture intended to be used by a silicon wafer doping unit, said plant make it possible to accurately control the composition of the mixture, while offering continuity and flexibility of delivery, in particular as a function of the requirements at the point of consumption of the mixture.

For this purpose, the solution of the present invention is a plant for delivering a gas mixture suitable for and intended to be used in a silicon wafer doping unit, said plant comprising:
a source of a dopant gas,
a source of a carrier gas,
a mixer device fluidically connected to the container of dopant gas and to the source of carrier gas, said mixer device being configured to produce, at an outlet, a gas mixture comprising the dopant gas and the carrier gas,
a first flow regulator member and a second flow regulator member which are configured to regulate respectively the flow of the dopant gas and the flow of the carrier gas flowing towards the mixer device according to a first flow rate setpoint and a second flow rate setpoint defining, in operation, a production flow rate of the gas mixture at the outlet of the mixer device,
a control unit configured to control the first and second flow regulator members so as to adjust the first flow rate setpoint and the second flow rate setpoint in respective proportions relative to the production flow rate, said respective proportions being determined as a function of at least one target content of dopant gas and/or carrier gas in the gas mixture,
a buffer tank connected by an outlet duct to the outlet of the mixer device on the one hand and to a delivery line on the other hand, the delivery line being configured to deliver the gas mixture to a silicon wafer doping unit with a consumption flow rate representative of a variable consumption of the gas mixture,
at least one measurement sensor configured to measure a physical quantity, the variation of which is representative of a variation in the consumption flow rate delivered by the delivery line and to provide a first measurement signal of said physical quantity, the control unit being connected to the measurement sensor and configured to produce a first control signal from the first measurement signal, the flow regulator members being configured to adjust the first flow rate setpoint and the second flow rate setpoint in response to said first control signal.

Depending on the case, the invention may comprise one or more of the features mentioned below.

The plant comprises a first analysis unit arranged downstream of the buffer tank and configured to analyse at least one respective content of dopant gas and/or carrier gas in the gas mixture delivered by the supply line.

The plant comprises a first sampling duct connecting the first analysis unit to the supply line at a first sampling point and a first return line connecting the first analysis unit to the supply line at a first return point, the return point being located downstream of the first sampling point on the supply line, a pressure-reducing valve being mounted on the supply line between the first sampling point and the first return point, preferably the pressure-reducing valve is mounted upstream of the measurement sensor.

The plant comprises a second analysis unit configured to measure at least one content of dopant gas and/or carrier gas in the gas mixture produced at the first outlet of the mixer device and to consequently provide at least a second measurement signal, the control unit being connected to the second analysis unit and configured to produce a second control signal from the second measurement signal and to modify the proportion of the first flow rate setpoint and/or the proportion of the second flow rate setpoint relative to the production flow rate in response to said second control signal.

The plant comprises a second sampling duct connecting the second analysis unit to the outlet line at a second sampling point and a second return line connecting the second analysis unit to the outlet line at a second return point, the return point being located downstream of the second sampling point on the outlet line, a backpressure regulator being mounted on the outlet line, between the second sampling point and the second return point.

The plant is configured to deliver a mixture having a content of dopant gas of between 0.0001% and 50%, preferably between 0.05% and 30% (% by volume).

The source of dopant gas contains germanium tetrahydride (GeH₄), phosphine (PH₃), arsine (AsH₃) and/or diborane (B₂H₆) and/or the source of carrier gas contains hydrogen (H₂), nitrogen (N₂) and/or argon (Ar).

The source of dopant gas contains a gaseous premix formed of dopant gas and carrier gas.

The plant comprises a first feedback loop from the first and second flow rate setpoints to the first measurement signal provided by the measurement sensor, said first loop comprising:
a first comparator arranged within the control unit and configured to produce at least a first error signal from the first measurement signal,
a first corrector arranged within the control unit, in particular of proportional, integral and derivative type, and configured to produce the first control signal from the first error signal,
actuators of the first and second flow regulator members which are connected to the first corrector and configured to receive the first control signal and move the first and second flow regulator members into respective positions in which the first flow rate setpoint and the second flow rate setpoint comply with the first control signal.

The plant comprises a second feedback loop from the respective proportions of the first flow rate setpoint and/or the second flow rate setpoint relative to the production flow rate to the second measurement signal provided by the second analysis unit, the second loop comprising:
a second comparator arranged within the control unit and configured to produce at least a second error signal from a comparison of the second measurement signal with at least one parameter chosen from: a target content of the dopant gas, a target content of the carrier gas,
a second corrector arranged within the control unit, in particular of proportional, integral and derivative type, and configured to produce the second control signal from the second error signal,
actuators of the first and second flow regulator members which are connected to the second corrector and configured to move the first and/or second flow regulator members into respective positions in which the proportions of the first flow rate setpoint and/or second flow rate setpoint relative to the production flow rate comply with the second control signal.

The measurement sensor comprises a flow sensor or flowmeter configured to measure the consumption flow rate.

The first comparator is configured to produce at least a first error signal representative of a variation in the consumption flow rate and the first corrector is configured to produce a first control signal controlling a movement of the first and second flow regulator members so that the first and second flow rate setpoints vary in the same direction as that of the variation in the flow rate.

The measurement sensor comprises a pressure sensor configured to measure the pressure prevailing in the buffer tank.

The first comparator is configured to produce a first error signal representative of a variation in the pressure in the buffer tank and the first corrector is configured to produce at least a first control signal controlling a movement of the first and second flow regulator members so that the first and second flow rate setpoints vary in the opposite direction to that of the variation in the pressure.

Moreover, the invention relates to an assembly comprising a silicon wafer doping unit comprising a furnace equipped with a chamber associated with heating means and a support arranged in said chamber on which wafers are installed, the furnace comprising means for introducing a mixture of dopant gas and of carrier gas into the chamber, characterized in that it further comprises a plant according to the invention, said introduction means being fluidically connected to the supply line of said plant.

### BRIEF DESCRIPTION OF THE DRAWINGS

The invention will now be better understood from the following detailed description, which is provided by way of a non-limiting illustration, with reference to the appended figures described below.

FIG. 1 schematically shows the operation of a plant according to one embodiment of the invention.

FIG. 2 schematically shows a first feedback loop according to one embodiment of the invention.

FIG. 3 represents an example of the change over time of the pressure prevailing in the buffer tank and of the production flow rate of the plant.

FIG. 4 represents an example of the controlled change over time of the content of a constituent of the gas mixture delivered by a plant according to one embodiment of the invention.

FIG. 5 represents an example of the change over time of the flow rate of the gas mixture delivered by a plant according to one embodiment of the invention with the content of a constituent of the mixture measured during this change.

### DETAILED DESCRIPTION OF PREFERRED EMBODIMENTS

FIG. 1 represents a plant according to the invention comprising a source of dopant gas 1 and a source of carrier gas 2. These gases may be single or mixed pure substances, or premixes of several pure substances, in particular one pure substance diluted with another.

The term “dopant” is understood to mean a gas capable of and suitable for doping silicon in the field of semiconductors, i.e. a gas that makes it possible to introduce, into the silicon matrix, atoms of another material in order to modify the conductivity properties of the silicon. As dopant gas, use may in particular be made of germanium tetrahydride (GeH₄), phosphine (PH₃), diborane (B₂H₆), arsine (AsH₃).

The term “carrier” is understood to mean a gas capable of and suitable for transporting the dopant gas to the silicon matrix, preferably a gas formed of one or more inert pure substances such as hydrogen (H₂), nitrogen (N₂) or argon (Ar).

Note that the expression “dopant gas” may cover a dopant pure substance, a mixture of several dopant pure substances or a premix comprising a dopant pure substance diluted in a non-dopant pure substance. Advantageously, the dopant gas is formed of a dopant pure substance diluted in another pure substance which is of the same nature as the one forming the carrier gas. As the dopants are highly reactive, some are customarily stored at very low temperature, typically −30° C., in the liquid state, in order to ensure the stability thereof. By using a premix of dopant gas diluted in carrier gas, the dopant is stored in the form of a gaseous mixture, which ensures the stability of the dopant and also a better homogeneity.

Thus, use may be made of a dopant gas composed of a dopant pure substance, in particular of 1% to 30% of dopant pure substance, preferably from 1% to 15%, and of carrier gas for the remainder, in order to ultimately provide dopant mixtures having contents of dopant gas ranging from 0.0001% to 30% in the carrier gas. For example, the dopant gas may comprise, as dopant pure substance, B₂H₆ with a content of 10% in H₂, then mixed with H₂, to provide dopant mixtures with contents of B₂H₆ in H₂ ranging from 0.05% to 5%.

Preferably, each of the gas sources is a container containing said gas, in particular a gas cylinder, typically a cylinder that may have a water volume of up to 50 L, or a set of cylinders connected to one another to form a bundle of cylinders or a tank of greater capacity, in particular a capacity of up to 1000 L, such as a cryogenic storage tank or a tank arranged on a lorry trailer.

In particular, the source of dopant gas is a container containing a dopant gas and the source of carrier gas is a container containing a carrier gas.

Preferably, the sources deliver fluids in the gaseous state. Before delivery, the fluids may be stored in the gaseous state, in the liquid state, i.e. liquefied gases, or a liquid gas two-phase state. Preferably, in the case of a dopant premix, this will be stored in the gaseous state.

FIG. 1 illustrates the case where the plant is configured to produce a binary gas mixture, i.e. containing two constituents, from two gas containers. Of course, a plant according to the invention could comprise more than two sources of gas and produce mixtures containing more than two constituents, in particular ternary or quaternary gas mixtures.

Each of the containers of dopant gas 1 and of carrier gas 2 is connected by a first line 21 and a second line 22 to respective first and second flow regulator members 41, 42. These are provided to regulate the flows of dopant gas and of carrier gas flowing towards the gas mixer device 3. Preferably, the lines 21, 22 join together at a connection point 31 located upstream of the mixer device 3 in order to form a shared line portion connected to an inlet 32 of the mixer device. A mixture of the dopant gas and carrier gas thus enters the device 3 in order to be further mixed and homogenized therein. Note that it can also be envisaged for the lines 21, 22 to open into two separate inlets 32a, 32b of the mixer device 3.

Preferably, each of the lines 21, 22 is provided with a pressure-reducing valve and a pressure sensor in order to measure and control the pressure prevailing in these lines. The pressures of the dopant gas and carrier gas may each be kept constant, typically at a value between 1 and 10 bar.

Each flow regulator member 41, 42 may be any means configured to set, regulate, adjust the flow rate of a fluid in order to bring it to a flow rate value closest to the desired value.

Typically, the flow regulator members 41, 42 each comprise a flow sensor, or flowmeter, combined with an expansion member, such as a valve, for example a proportional control valve. The valves may be pneumatic or piezoelectric, analogue or digital. The valve comprises a moving part, typically at least one closure member, which is placed in the flow of fluid and the displacement of which makes it possible to vary the flow area, and thus to vary the flow in order to bring it to the setpoint value. In particular, the flow regulator members 41, 42 may be mass flow regulators comprising a mass flow sensor and a proportional control valve. Note that even if the regulation is based on a measurement of mass of fluid, the setpoint and measured flow values are not necessarily expressed by mass. Thus, a volume flow setpoint may be expressed as a percentage opening of the proportional control valve, to which a voltage value to be applied to the control valve of the regulated member corresponds. The conversion between percentage opening to mass or volume flow value is achieved by knowing the nominal value of the regulated flow for 100% opening.

According to one advantageous embodiment, the valve is piezoelectric. This type of valve offers great accuracy, good reproducibility enabling the monitoring of the voltage applied to the valve. Such valves are also relatively insensitive to magnetic fields and radio-frequency noise. Their energy consumption is low with minimal heat generation. The metal on metal control surface reduces, or even eliminates, reactions with the gas. Finally, owing to a relatively small flow control cavity volume, in particular compared to that of a solenoid valve, it is possible to have a rapid replacement of the gas and an excellent dynamic response.

In practice, the first and second flow regulator members 41, 42 make it possible to regulate, respectively, the flow of dopant gas and the flow of carrier gas entering the mixer 3 according to a first flow rate setpoint D1 and a second flow rate setpoint D2. At the outlet 33 of the mixer device 3 the gas mixture in an outlet line 23 with a production flow rate DP corresponds, in the case of a plant with two gas sources, to the sum of the two flow rates D1 and D2 of dopant gas and carrier gas. If the plant comprises for example a source of a third gas, the flow rate DP will be the sum of flow rates D1, D2, D3 regulated by corresponding flow regulator members 41, 42, 43 in the direction of the mixer device 3.

The plant according to the invention further comprises a control unit 5 which is connected to the first and second flow regulator members 41, 42 so as to control the operation thereof, in particular so as to adjust the setpoint values D1, D2 in order to bring them to values which are determined and suitable as a function of the operating conditions of the plant.

To do this, the flow regulator members 41, 42 each advantageously comprise a closed-loop system which is given flow setpoints by the control unit 5. These setpoints are then compared by the closed-loop system to values measured by the flow regulator members 41, 42 and the positions thereof are consequently adjusted by said system to send flows as dose as possible to al D2 to the mixer device 3.

Advantageously, the control unit 5 comprises a programmable controller, also referred to as a PLC (Programmable Logic Controller) system, i.e. a control system for an industrial process comprising a man-machine interface for supervision and a digital communication network. The PLC system may comprise several modular controllers which control the control sub-systems or equipment of the plant. These pieces of equipment are each configured to ensure at least one operation from among: acquisition of data from at least one measurement sensor, control of at least one actuator connected to at least one flow control member, the regulation and feedback of parameters, the transmission of data between the various pieces of equipment of the system.

The control unit 5 may thus comprise at least one from among: a microcontroller, a microprocessor, a computer. The control unit 5 may be connected to the various pieces of control equipment of the plant, in particular to the flow regulator members 41, 42, to the sensor 8, and communicate with said piece of equipment by electrical, Ethernet, Modbus, etc. connections. Other modes of connections and/or transmission of information can be envisaged for all or some of the equipment of the plant, for example by radiofrequency, WIFI, Bluetooth, etc. connections.

Firstly, the electronic logic 5 calculates a predetermined proportion of the flow rate D1 relative to a production flow rate DP and/or a predetermined proportion of the flow rate D2 relative to DP, i.e. predetermined D1/DP and/or D2/DP ratios, as a function of a target content C1 of dopant gas in the gas mixture and/or of a target content C2 of carrier gas in the gas mixture.

Preferably, the electronic logic 5 does not perform a calculation of the carrier gas flow rate D2 from a target content C2 of carrier gas but sets D2 by deduction from D2 then corresponds to DP from which D1 is subtracted, Preferably, the electronic logic 5 calculates a predetermined proportion of the flow rate D1 relative to DP from a target content C1 which is that of the minor gas of the mixture.

Note that for a ternary mixture for example, D1 and D2 will be able to be set from the respective target contents C1 C2, the third flow rate setpoint D3 of the third gas being deduced from the values of D1 and D2.

According to one possibility of implementation, the control unit 5 comprises a man-machine interface 300 comprising an input interface, for example a touch screen, enabling the input by a user of said at least one target content of the dopant gas and/or of the carrier gas in the gas mixture. For example, the contents may be expressed as a volume percentage of dopant gas or carrier gas present in the gas mixture. More generally, the man-machine interface 300 may enable the user to give instructions to the control unit 5.

The flow regulator members 41, 42 receive the order from the control unit 5 to regulate the flow of the dopant gas and carrier gas to the respective setpoints D1, D2 determined from the target composition for the gas mixture. It is with these flow rates that the dopant gas and the carrier gas enter the mixer device 3.

Typically, the mixer device 3 comprises a common mixer volume into which the inlet 32 and the outlet 33 open and in which the mixture is homogenized. Use could for example be made of a mixer 3 of static mixer type enabling a continuous mixing of the fluids entering the mixer. This type of mixer generally comprises at least one disturbing element, such as a plate, a portion of pipe, an insert, capable of disturbing the flow of the fluids, generating pressure drops and/or turbulence in order to promote the mixing of the fluids and the homogenization thereof.

A mixture of dopant gas and carrier gas is therefore produced at the outlet 33 of the mixer device 3 with a production flow rate DP. The flow rates D1 and D2 are governed by the flow rate DP and by the desired contents C1, C2 of dopant gas and carrier gas.

One problem that arises concerns the delivery of a gas mixture to a consuming unit 10 for which the demand for gas mixture fluctuates. It follows therefrom that the flow rate for conveying the gas mixture to point 10 will vary.

In order to adapt the flow rate of gas mixture produced at the outlet of the mixer device to the flow rate of gas consumed, the present invention proposes to connect the outlet 33 of the mixer 3 to the inlet of a buffer tank 7 via the outlet line 23. A delivery line 6 is fluidically connected to an outlet of the buffer tank 7 and makes it possible, in operation, to deliver the mixture to the consuming unit 10.

Note that the plant may comprise a venting line 25 fluidically connected to the buffer tank 7 with a vent 15 linked to a relief valve, of use in the event of overpressure, and to a valve controlling the passage of the mixture to a gas reprocessing unit. The valve makes it possible, during phases of starting up the delivery to the consuming unit, to purge the lines of the plant and the buffer tank 7.

The delivery of the gas mixture to the consuming unit 10 therefore takes place from the buffer tank 7 with a consumption flow rate DC corresponding to the consumption of mixture by the consuming unit 10. If the flow rate DC varies during the operation of the delivery plant, the production flow rate DP upstream of the buffer tank 7 may no longer correspond to the demand for mixture. The buffer tank 7, owing to the supplementary volume that it provides to the fluid circuit, makes it possible to ensure a delivery at the flow rate DC even if it does not correspond to the flow rate DP. In particular, if DP is greater than DC, the tank 7 prevents the gas mixture from being forced towards the delivery line and thus absorbs the overproduction. And if DP is less than DC, the buffer tank 7 forms a reserve of mixture from which the user can draw on, for example when a consumption begins too rapidly with a high consumption flow rate, which makes it possible to ensure the delivery at the flow rate DC even in an underproduction situation.

Moreover, the plant comprises a measurement sensor 8 which measures a physical quantity, the variation of which is representative of a variation in the consumption flow rate DC flowing in the delivery line 6 and provides a corresponding first measurement signal to the control unit 5. In particular, the first measurement signal may comprise several successive measurements taken by the sensor 8. The unit 5 receives it and produces a first control signal which is transmitted to the flow regulator members 41, 42 so as to adjust the first flow rate setpoint D1 and the second flow rate setpoint D2 in accordance with the first control signal.

The present invention thus makes it possible to recalculate the flow rate setpoints D1 D2 set initially in order to adapt them to a variation in the consumption flow rate DC and therefore to the demand of the user. The mixer device 3 produces a mixture flow rate, the control of which is associated with the flow rate consumed.

Note that at the same time, the control unit 5 continues to monitor the D1/DP and D2/DP ratios so that they are in accordance with the contents of dopant gas and carrier gas desired for the gas mixture.

The process according to the invention advantageously implements a start-up phase during the start of a consumption of mixture by the consuming unit, when no consumption was detected before. During this start-up phase, there is a change from a zero production flow rate DP to a production of a mixture of dopant gas and carrier gas with a predetermined production flow rate DP.

In practice, in the start-up phase, the user can start up the production of gas mixture with a predetermined flow rate DP which can be set to a minimum “start-up” value corresponding to a predetermined percentage of the maximum production flow rate that can be produced. This maximum production flow rate corresponds to the sum of a first maximum flow rate value and of a second maximum flow rate value that the first and second regulator members 41, 42 are designed to deliver. Advantageously, the predetermined percentage is at least 25%, preferably at least 35% and more preferably at least 50% of the maximum production flow rate. This makes it possible to use the sensor which measures the D1, D2 flow regulators in its optimal and most accurate operating range.

Note that during the delivery to the consuming unit, the gas mixture produced can be delivered to the vent 15, in the case in particular where the composition of the mixture might not comply with the target composition.

The user may optionally first set a higher production flow rate than the expected consumption flow rate DC in order to fill the buffer tank 7 and constitute a reserve of mixture therein.

After the start-up phase of the consumption, a phase of regulating the production follows during which the production flow rate DP is adjusted as a function of the consumption flow rate DC. During the regulating phase, the control unit 5 monitors the consumption flow rate DC via the measurements received from the measurement sensor 8. If a change in the consumption flow rate DC is detected, the control unit 5 produces a first control signal to adapt the flow rates D1, D2 delivered upstream of the mixer in order to bring the flow rate DP into line with the modified flow rate DC.

Preferably, the measurement sensor 8 takes measurements continuously or quasi-continuously. Preferably, the control unit 5 is configured so that the production of the first control signal and/or the transmission of the first control signal to the flow regulator members only takes place at a predetermined time interval, in particular an interval of the order of 1 to 60 seconds. In other words, the flow rate setpoints are maintained during this time interval, without an adjustment of the setpoints being ordered by the control unit 5. This makes it possible to prevent a reaction of the plant following inadvertent fluctuations of the flow rate DC or else to avoid generating excessively rapid variations of the flow rate DP which could give rise to operating errors.

Optionally, depending on the amplitude and/or the speed of variation of the flow rate DC, the control unit 5 may be configured to, at least temporarily, maintain the production flow rate DP. For example, if the consumption flow rate DC increases, the consuming unit 10 may draw on the buffer tank 7 to compensate for the underproduction of the mixer 3. If the consumption flow rate DC decreases, the buffer tank 7 may fill up to absorb the overproduction of the mixer 3.

Preferably, the control unit 5 is configured so as to stop the gas streams when the physical quantity measured by the sensor 8 is representative of a zero consumption flow rate DC. Thus, in the absence of demand, the plant does not produce a gas mixture. The control unit 5 may also be configured to stop the gas streams if the physical quantity measured by the sensor 8 is representative of a low consumption flow rate DC, i.e. lower than a given low flow rate threshold, in order to avoid overpressure in the buffer tank 7. The control unit 5 may also be configured to generate an alarm signal when the physical quantity measured by the sensor 8 is representative of a consumption flow rate DC above a given high flow rate threshold.

Advantageously, the plant according to the invention uses a first feedback loop from the first and second flow rate setpoints D1, D2 to the first measurement signal. A “feedback loop” is generally understood to mean a system for monitoring a process in which a regulating quantity acts on a regulated quantity, i.e. a quantity to be fed back, in order to bring it as quickly as possible to a setpoint value and maintain it thereat, The basic principle of a feedback is to measure, continuously, the difference between the actual value of the quantity to be fed back and the setpoint value that it is desired to achieve, and to calculate the appropriate command to apply to one or more actuators so as to reduce this difference as quickly as possible. It is also referred to as a closed-loop controlled system.

In the first feedback loop, the regulating quantity is the physical quantity measured by the measurement sensor 8, the regulated quantity is the production flow rate DP, via the adjustment of the flow rates D1 and D2 of dopant gas and carrier gas. The setpoint is variable depending on the conditions for consumption of the mixture.

Besides the sensor 8, the first feedback loop comprises a first comparator 11A arranged within the control unit 5 and configured to produce at least a first error signal from the first measurement signal. The first error signal may be representative of a variation in the physical quantity measured. It is advantageously obtained by comparison with at least one measurement of said physical quantity carried out at another instant.

Furthermore, the first feedback loop comprises a first corrector 12A arranged within the control unit 5 and configured to produce the first control signal from the first error signal.

The first corrector 12A sends the control signal to actuators which control a movement, in response to the first control signal, of the first and second flow regulator members 41, 42 into respective positions in which the first flow rate setpoint D1 and the second flow rate setpoint D2 are adjusted in accordance with the first control signal. Typically, the actuators control the movement of the moving parts within the regulator members, which vary the flow rates D1, D2 sent to the mixer device 3 in a direction that tends to reduce the difference between the flow rates DP and DC.

Preferably, the first corrector 12A is of proportional, integral and derivative (PID) type, which makes it possible to improve the performance of a feedback owing to three combined actions: a proportional action, an integral action, a derivative action.

Preferably, and as mentioned above, the corrective action of the first feedback loop is only applied to the setpoints D1, D2 at a predetermined time interval, preferably an interval between 1 and 60 s, more preferably of the order of 20 s, in order to prevent excessively rapid variations of the production flow rate which may create errors. This time interval may be a parameter of the first corrector 12A.

The first corrector 12A may in particular comprise a microprocessor, memory registers, programming instructions for processing the first error signal and producing, by numerical calculation, the proportional, integral and derivative terms of the feedback loop. These terms, which may be determined by calculation and/or experimentally, are combined to provide the control signal for the regulator members 41, 42. The derivative term may optionally be zero.

FIG. 1 illustrates an embodiment in which the measurement signal is obtained by a flow rate sensor 8, also referred to as a flowmeter, arranged on the delivery line 6 so as to directly measure the consumption flow rate DC delivered to the consuming unit 10. The signals received and sent to the various elements of the plant are shown schematically by the dashed lines referenced “A”.

Typically, if the flow rate DC increases, the control signal orders an increase of the first and second flow rate setpoints D1, 02 and a decrease of the first and second flow rate setpoints D1, D2 if the flow rate DC decreases.

Note that in the context of the invention, each of the first and second flow regulator members 41, 42 can be moved between a closed position in which the first flow rate setpoint D1 or the second flow rate setpoint D2 is zero and a completely open position in which the first flow rate setpoint D1 or the second flow rate setpoint D2 respectively have a first maximum flow rate value or a second maximum flow rate value.

The first and second flow regulator members 41, 42 may optionally occupy at least one intermediate position between the closed position and the open position. Preferably, said intermediate position corresponds to a first flow rate setpoint D1 or a second flow rate setpoint D2 greater than or equal to a first minimum flow rate value or a second minimum flow rate value. Preferably, the first minimum flow rate value and/or the second minimum flow rate value is equal to at least 25%, more preferably at least 35%, or at least 50%, of the respective first or second maximum value. This makes it possible to work in flow rate ranges where the accuracy of the regulator members 41, 42, more specifically the accuracy of the flow rate sensors used in the regulator members, is better.

Optionally, these positions may be predefined, in order to increase, incrementally and in a controlled manner, the flow rates in the desired range, which makes it possible to better control the accuracy of the mixture, owing to the first feedback loop.

According to one embodiment variant, the plant uses a pressure sensor 8 that measures the pressure prevailing in the buffer tank 7 as a physical quantity representative of the consumption flow rate DC. The fluctuations in consumption flow rate DC are thus determined indirectly, via the determination of the pressure fluctuations in the buffer tank 7. The representation from FIG. 1 remains applicable except that the measurement signal is produced by the sensor 8 connected to the buffer tank and not by the sensor 8 connected to the line 6.

Note that the plant according to the invention may comprise two sensors 8, one a flow rate sensor and the other a pressure sensor. These sensors are as described above and each produce a respective first measurement signal. Depending on the predetermined choice criteria, the control unit 5 is configured to produce the first control signal from the measurement signal originating from one or other of the sensors 8. Preferably, the control unit 5 chooses to use the first measurement signal originating from the one of the two measurement sensors 8 that measures a physical quantity value representative of the highest flow rate.

In practice, if the consumption flow rate DC increases, the production flow rate DP produced at the outlet of the mixer device 3 will begin to become insufficient. The consuming unit 10 will draw on the buffer tank 7 to compensate for the underproduction of the mixer 3, leading to a decrease of the pressure in the tank 7.

The pressure sensor 8 sends the first measurement signal to the first comparator 11A which produces a first error signal corresponding to the pressure drop information and transmits it to the first corrector 12A so that it calculates a first control signal applied to the first and second flow regulator members 41, 42 so that the first and second flow rate setpoints D1, D2 increase by an appropriate factor, which may be determined by the first control loop.

According to one embodiment possibility, the first comparator 11A is configured to produce at least a first error signal from a comparison of the first measurement signal with at least one parameter chosen from: a low pressure threshold, a high pressure threshold. These thresholds may be adjusted as a function of the operating conditions, of the characteristics of the plant, etc. When the pressure in the buffer tank 7 reaches the low pressure threshold, the first corrector orders the flow regulator members to regulate the flow of the dopant gas and carrier gas according to given flow rate setpoints D1, D2.

This operating mode may be used during the regulating phases and also during the start-up phases of the consumption. In the case of a start-up phase, as soon as the pressure in the buffer tank 7 reaches the low pressure threshold, the flow regulator members are ordered to regulate the flow of the dopant gas and carrier gas so as to produce the gas mixture with the flow rate DP set at the start-up value. In particular, the flow rate setpoints D1, D2 may correspond respectively to the first minimum flow rate value and the second minimum flow rate value. The flow regulator members 41, 42 each begin to produce minimum flow rates leading to a flow rate DP equal to the start-up value until the high pressure threshold in the buffer tank 7 is attained.

According to one possibility, if the pressure in the tank 7 does not increase sufficiently, in particular if the high pressure threshold is not attained, or if the pressure does not increase rapidly enough, the flow rate setpoints D2 are increased by following a scheme of regulation by the first corrector 12A, preferably of PID type, in which the increase in the flow rates is a function of the drop in pressure.

If the pressure in the tank 7 attains the high pressure threshold, the flow regulator members 41, 42 may be moved towards their respective closed positions in which the flow rates D1, D2 are zero.

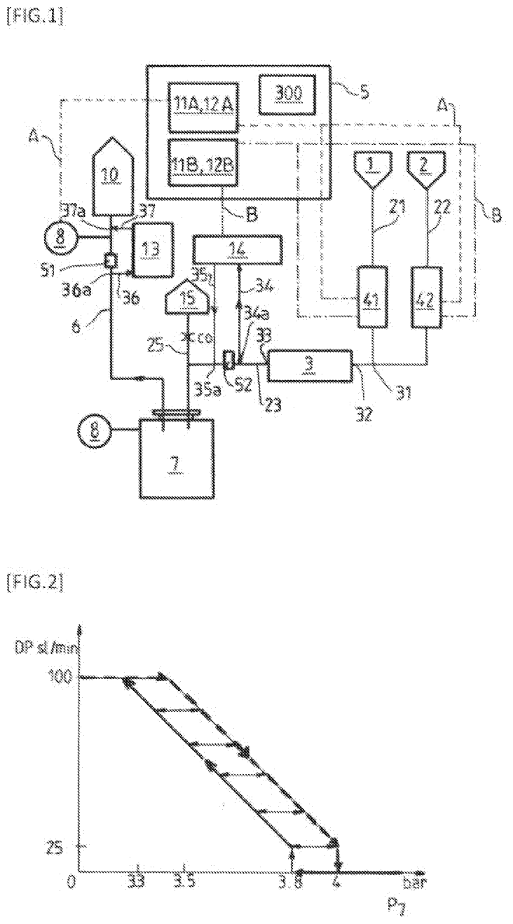

FIG. 2 schematically shows an example of the effect of a first feedback loop with a first corrector of PID type in which the production flow rate DP, corresponding to the sum of D1 and D2, is corrected as a function of the variation of the pressure P7 in the buffer tank 7. The maximum production flow rate DP of the plant, corresponding to the sum of the first and second maximum flow rate values, is set at 100 sL/min (standard litres per minute), i.e. 6 Nm³/h (normal cubic metres per hour). The minimum production flow rate DP of the plant, corresponding to the sum of the first and second minimum flow rate values, is set at 25 sL/min (standard litres per minute), i.e. 1.5 Nm³/h. The high and low pressure thresholds are set respectively at 4 bar and 3.8 bar.

FIG. 2 schematically represents various scenarios which may be encountered during the operation of the plant. If DP=DC, the pressure remains stable at 4 bar (grey arrow on the bottom right of FIG. 2). Subsequently, assuming that DC>0 but DP=0, the pressure in the buffer tank will drop to 3.8 bar (displacement to the left along the grey arrow). This pressure is the start-up pressure of the flow regulators. The flow rate DP is at its minimum start-up value, i. e. 25 sL/min. As soon as the control unit has ordered the flow regulators to produce a flow rate DP<DC, the pressure will drop until a DC flow rate equal to the maximum DP flow rate of the plant, i.e. 100 sL/min, is attained (upwards displacement along the grey arrows). As soon as DC decreases, i.e. DP-DC, the buffer tank begins to fill up and the pressure increases from 3.5 bar to 4 bar (by following the arrows with black dashes). 4 bar is the pressure at which filling of the buffer tank stops.

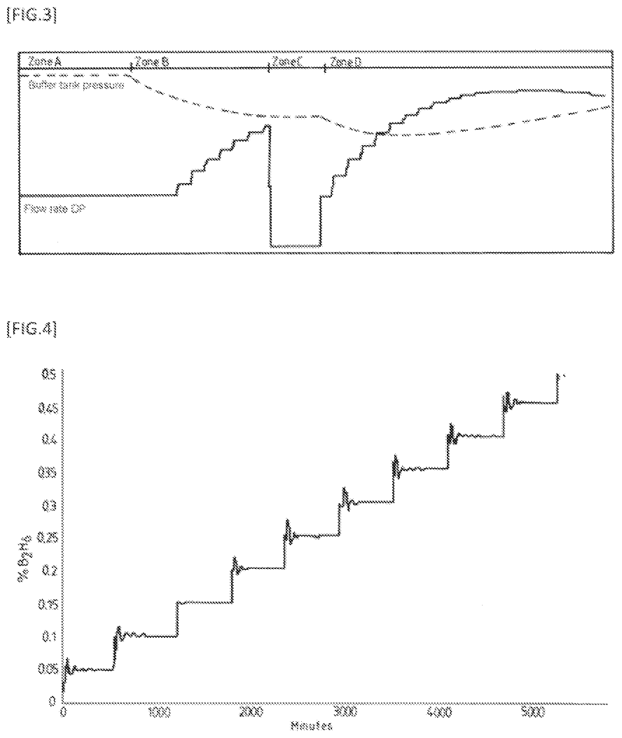

An example of what happens in practice is represented in FIG. 3 showing the change over time of the pressure prevailing in the buffer tank (dashed curve) and of the production flow rate DP (solid-line curve). At the start of the graph (zone A), if there is no drop in the pressure, the flow rate setpoint remains at 0. As soon as the pressure drops (zone B), flow rate setpoints are given to the flow regulators D1 and D2, which are increased by increments at a regular interval if the pressure does not stabilize. As soon as the pressure is stabilized, the buffer tank stops being filled (zone C). If the pressure drops again (zone D), the setpoints of the flow regulators will be adjusted to the desired values in order to make it possible to provide the consumption DC and to keep the pressure of the buffer tank stable.

It should be noted that the normal cubic metre is a unit for measuring the amount of gas which corresponds to the content of a volume of one cubic metre, for a gas that is under normal temperature and pressure conditions (0° C. or 15° C. or less commonly 20° C. depending on the frames of reference and 1 atm, i.e. 101 325 Pa). For a pure gas, one normal cubic metre corresponds to around 44.6 mol of gas.

Note that the buffer tank advantageously has an internal volume equal to at least half of the maximum production flow rate DP of the plant.

$$Minimum buffer volume = \frac{{DP}_{max}}{2}$$

Complying with this minimum internal volume makes it possible to absorb the pressure variations linked to the inadvertent nature of DC. The buffer tank may have an internal volume of at least 1 L, or at least 50 L, or even 1000 L or more. Preferably, the internal volume of the buffer tank will be between 50 and 400 L. The tank may be formed of a single tank or several tanks fluidically connected to one another, the internal volume of the buffer tank then being understood as the sum of the volumes of the tanks.

In one advantageous embodiment, as seen in FIG. 1, the plant may further comprise a first analysis unit 13 configured to analyse at least one content of dopant gas and/or carrier gas in the gas mixture delivered by the supply line 6. This makes it possible in particular, during the start-up phase of the plant, to condition the delivery of the gas mixture so that the measured contents comply with the target contents. A tolerance of the order of from 0.01% to 5% (relative %) relative to the target contents C1, C2 may be set. If the mixture produced does not comply, the production may optionally be stopped, Preferably, the first analysis unit 13 is configured to analyse the content of dopant gas, which may in particular be the minor gas in the gas mixture.

Advantageously, the plant comprises a first sampling duct 36 connecting the first analysis unit 13 to the supply line 6 at a first sampling point 36a. A portion of the mixture flowing in the supply line 6 from the tank 7 is thus sampled by the first sampling duct 36 in order to be analysed in the first analysis unit 13. After passing through the first analysis unit 13, the sampled mixture returns to the supply line 6 via a first return duct 37 connected to the supply line 6 at a first return point 37a which is located downstream of the first sampling point 36a on the supply line 6. Since the gas mixture is a high-precision and high-added-value dopant gas, this recirculation scheme prevents the discharge and loss of the mixture. Moreover, it avoids a possible retreatment of the discharged mixture which would be expensive and complex for the user in view of the nature of the gases used.

The plant further comprises at least one pressure-reducing valve 51 mounted on the supply line 6 between the first sampling point 36a and the first return point 37a. The pressure-reducing valve functions as a downstream pressure reducer and makes it possible to ensure the pressure difference necessary for the flow of the gas mixture through the first sampling and return ducts 36, 37. Moreover, the pressure-reducing valve 51 is configured to regulate the pressure of the gas mixture delivered to the silicon wafer doping unit 10. The stability of the pressure at the point of use is thus ensured in order to meet the requirements of a silicon doping unit in terms of accuracy and stability of the parameters of the mixture. In particular, the pressure-reducing valve 51 may be mounted in series on the supply line 6.

The plant according to the invention may also comprise a second analysis unit 14 arranged upstream of the buffer tank 7 so as to measure at least one content of dopant gas and/or carrier gas in the gas mixture produced by the mixer device 3. Depending on the case, the invention may comprise one and/or the other of the first 13 and second 14 analysis units. The second analysis unit 14 is configured to consequently provide at least a second measurement signal destined for the control unit 5, which produces a second control signal from the second measurement signal. The second control signal is used to control one and/or the other of the flow regulator members 41, 42 so as to adjust one and/or the other of the proportions of the first flow rate setpoint D1 and of the second flow rate setpoint D2 relative to the production flow rate DP so that the actual composition of the gas mixture leaving the mixer device 3 approaches the target composition with contents C1, C2 (C2 preferably being deduced from C1 and not measured). The signals received and sent to the various elements of the plant within the context of control of the composition of the mixture are shown schematically by the dashed lines “B”.

This control of the contents of the mixture produced by the mixer device makes it possible to compensate for possible errors between the flow rates actually regulated by the flow regulator members 41, 42 and the flow rate setpoints D1, D2 which are applied thereto. The arrangement of a sampling point located between the outlet of the mixer device and the inlet of the buffer tank 7 makes it possible to detect and to react more rapidly to possible variations in contents, thus avoiding the risk of consuming a non-compliant mixture.

Advantageously, the plant comprises a second sampling duct 34 connecting the second analysis unit 14 to the outlet line 23 at a second sampling point 34a and a second return line 35 connecting the second analysis unit 14 to the outlet line 23 at a second return point 35a, the return point 35a being located downstream of the second sampling point 34a on the outlet line 23. As already explained, since the gas mixture is a high-precision and high-added-value dopant gas, this recirculation scheme prevents the discharge and loss of the mixture. Moreover, it avoids a possible retreatment of the discharged mixture which would be expensive and complex for the user in view of the nature of the gases used.

The plant further comprises at least one backpressure regulator 52 mounted on the outlet line 23 between the second sampling point 34a and the second return point 35a.

When the pressure varies upstream, the backpressure regulator then modifies the flow rate in the bypass line so that its inlet pressure remains constant and so that a constant flow rate passes through the outlet line 23. In fact, the backpressure regulator 52 comprises a member which closes when the upstream pressure is greater than a predetermined threshold. The backpressure regulator 52 opens and becomes passable at a given flow rate when the upstream pressure is lower than this threshold, or as a function of a pressure difference between the upstream and downstream ends of the backpressure regulator.

According to one embodiment, the backpressure regulator may comprise a chamber mounted in bypass, a valve operated by a control membrane. This membrane is balanced on the one hand by a weighted spring provided to close and open a duct connected to the gas circuit and on the other hand by the pressure to be stabilized upstream.

The backpressure regulator 52 carries out several functions. It functions as an upstream pressure regulator, that is to say that it is configured to regulate the pressure of the gas mixture in the gas circuit upstream of said backpressure regulator 52, in particular at the outlet 33, in the mixer 3, at the inlet 31 of the mixer, at the regulator members 41, 42.

During the phases of regulating the production during which a flow rate DP is produced and adjusted as a function of the flow rate DC, the buffer tank 7 fills up and the pressure in the tank 7 varies as a function of the variations in consumption. These pressure fluctuations are also found at the inlet 31 in the lines 21, 22 in communication with the tank, which may skew and/or disturb the flow rate measurements carried out by the flow regulator members 41, 42. The use of the backpressure regulator 52 makes it possible to keep the upstream pressure constant, while the downstream pressure may fluctuate. In this way, the accuracy and the stability of the composition of the dopant mixture are greatly improved.

Furthermore, when the consumption ceases, the pressure in the tank 7 has a tendency to increase. As soon as the flow rate DP stops, the backpressure regulator 52 confines the mixture in the upstream circuit, which makes it possible to keep it at the desired pressure when the plant is shut down. At the start-up, when the mixer 3 begins to produce the mixture at the flow rate DP, the backpressure regulator makes it possible to reduce the time needed for the flow regulators 41, 42 to reach their setpoints, i.e. the start-up time of the flow regulator members 41, 42. Typically, it was possible to obtain response times of the regulators 41, 42 of less than 1 second, or less than a few milliseconds.

The backpressure regulator 52 also makes it possible to ensure the pressure difference necessary for the flow of the gas mixture through the first sampling and return ducts 36, 37.

Note that the second sampling duct 34 that samples the mixture and conveys it to the analysis unit 14 advantageously has the shortest possible length so that the analyser provides a very accurate response in real-time or in virtually real-time. Preferably, the line is such that the interval between the moment when the mixture is sampled at its sampling point and the moment when the analysis unit gives its measurement is minimal, typically less than 30 seconds, in particular between 1 and 30 seconds.

Preferably, the second control signal is produced from a second error signal containing at least one piece of information on the difference between a measured content and a target content, for the dopant gas or the carrier gas. Preferably, only the content of the dopant gas is measured and compared to its target value, the dopant gas being the minor gas of the mixture. This difference may in particular be expressed as:

$$Δ {C}_{1} = \frac{{M}_{1} - {C}_{1}}{{C}_{1}}$$

where M1 is the content measured for the dopant gas. The relative difference ΔC1 may be used as a correction factor for the first flow rate setpoint D1.

Consider the example of a plant configured to produce a mixture of two gases with a production flow rate DP at the outlet of the mixer device 3 of 100 sL/min. The desired gas mixture is a mixture formed of the dopant gas with a target content C1 of 0.5% and of the carrier gas for the remainder, therefore with a content C2 of 99.5% (volume %). A premix comprising a dopant pure substance diluted to 30% by volume in a carrier gas is used for the flow rate D1. A first flow rate setpoint D1 of 1.667 sL/min in (0.1 Nm³/h), corresponding to a proportion of 1.667% relative to DP, and a second setpoint D2 of 98.333 sL/min (5.1 Nm³/h) corresponding to a proportion of 98.333% relative to DR are therefore applied to the respective flow regulator members 41, 42. A control accuracy of the members 41, 42 of plus or minus 1% is assumed. An error of −1% in D1 and of +1% in D2 results in an actual flow rate of dopant gas equal to 1.650 sL/min, in an actual flow rate of carrier gas equal to 99.316 sL/min and in an actual production flow rate of 100.967 sL/min. A dopant gas content of 0.49% is measured at the outlet of the mixer device 3, corresponding to a difference ΔC1 of −1.95% (relative %) relative to the target content C1. The control unit 5 produces a second control signal ordering, at the flow regulator members 41, 42, an adjustment of the flow rate proportions D1 and D2 relative to DP so as to compensate for this difference. The first setpoint D1 is therefore adjusted to D1=1.682 sL/min.

Preferably, only the first setpoint D1 is adjusted as a function of the second measurement signal, the control unit 5 controlling the maintenance of D2. It being understood that it can be envisaged for D2 to also be adjusted in response to the second control signal. In the example above, D2 would be adjusted to 97.4 sL/min. Note that the correction may also be performed by the application of a correction factor to at least one of the target contents recorded beforehand in the control unit 5, in the example above a correction by a factor equal to 0.78%, which has the effect of consequently adjusting D1 to 1.682 sL/min.

Optionally, the plant may comprise an alarm configured to emit an alarm signal if the first analysis unit and/or the second analysis unit detects contents outside of the anticipated tolerance ranges.

The first analysis unit 13 and/or the second analysis unit 14 may be chosen in particular from the following types of detectors; a thermal conductivity detector, a paramagnetic alternating pressure detector, a catalytic adsorption detector, a non-dispersive infrared absorption detector, an infrared spectrometer, an analyser of gas concentration with acoustic or photo-acoustic wave propagation. The type of analysis unit will be able to be adapted depending on the nature of the gases to be analysed. The first 13 and second 14 analysis units could optionally be swapped around.

According to one embodiment, the plant may comprise a second feedback loop from the respective proportions of the first flow rate setpoint D1 and/or the second flow rate setpoint D2 relative to the production flow rate DP to the second measurement signal provided by the second analysis unit 14.

In the second feedback loop, the regulating quantities are the content(s) measured by the second analysis unit 14, and the regulated quantities are one and/or the other of the proportions D1/DP, D2/DP. The setpoint is variable depending on the actual content(s) measured.

The second loop comprises a second comparator 11B arranged within the control unit 5 and configured to produce at least a second error signal from a comparison of the second measurement signal with at least one parameter chosen from: the target content C1 of the dopant gas, the target content C2 of the carrier gas. A second corrector 12B is arranged within the control unit 5, in particular of PID type, and configured to produce the second control signal from the second error signal. In response to the second control signal, the actuators of the first and second flow regulator members 41, 42 order the movement of the first and second flow regulator members 41, 42 into respective positions in which the proportions of Q1 and/or D2 relative to DP comply with the second control signal. Preferably, only the proportion of D1 is adjusted, the control loop ordering D2 to remain fixed.

Note that the first comparator and the second comparator may optionally form one and the same entity configured to receive, as input data, both the measurements from the sensor 8 and from the second analysis unit 14 and to produce, as output, the appropriate error signals. The same is true for the first and second correctors.

The plant according to the invention may be used for delivering gas mixtures used in various industries such as the semiconductor, photovoltaic, LED and flatscreen industries or any other industry such as the mining, pharmaceutical, space or aeronautical industries.

Preferably, the plant comprises at least one gas cabinet, installed in which are at least the control unit 5, the mixer device 3, the flow regulator members, the measurement sensor 8, the buffer tank 7. The sources of dopant gas and carrier gas may be located in or outside of the cabinet. Preferably, the sources are located outside of the cabinet so that this cabinet retains a reasonable footprint. Preferably, the control unit 5 is arranged outside of the cabinet, either by being fixed to one of the wads of the cabinet, or positioned at a distance from the cabinet.

The gas cabinet may comprise a housing with a rear wall, side walls, a front wall, a base and a ceiling. In the housing, one or more buffer tanks are provided which stand on the base and may be fixed in the housing in a manner known in the prior art. A system of gas ducts is arranged in said housing, preferably against the base of the cabinet. The cabinet may comprise means for controlling and/or maintaining the system of gas ducts such as valves, pressure-reducing valves, pressure measurement members, etc., making it possible to carry out operations such as delivery of gas, opening or dosing of certain ducts or portions of ducts, management of the gas pressure, performing of purge cycles, leak tests, etc.

The housing comprises gas inlet openings for a supply with the dopant gas and carrier gas and a gas outlet opening for delivering the gas mixture. The delivery line 6 is connected to the outlet opening. In operation, the gas cabinet is connected to the consuming unit by the delivery line 6. Other gas inlets may be provided, in particular for a purging gas or a gas which creates the vacuum by the Venturi effect, and a gas standard for calibrating the analysers.

The plant according to the invention may particular be used to produce gas mixtures having the following compositions:
2% of AsH₃ in Ar,
1 to 10% of AsH₃ in He, in particular contents of 1%, 2% or 10% of AsH₃ in He,
1 to 20% of AsH₃ in H₂, in particular contents of 1%, 3%, 4%, 5%, 7%, 10%, 15% or 20% of AsH₃ in H₂,
1 to 10% of AsH₃ in N₂, in particular contents of 1%, 2%, 5% or 10% of AsH₃ in N₂,
1 to 10% of B₂H₆ in Ar, in particular contents of 1%, 2%, 3%, 4%, 5% or 10% of B₂H₆ in Ar,
1 to 10% of B₂H₆ in Hz, in particular 1% or 10% of B₂H₆ in H₂,
1 to 10% of B₂H₆ in N₂, in particular 1%, 2%, 3%, 4%, 5% or 10% of B₂H₆ in N₂,
1 to 15% of PH₃ in Ar, in particular 1%, 2%, 5%, 10% or 15% of PH₃ in Ar,
1 to 10% of PH₃ in He, in particular 1%, 2% or 10% of PH₃ in He,
1 to 15% of PH₃ in H₂, in particular 1%, 5%, 10% or 15% of PH₃ in H₂,
1 to 15% of PH₃ in N₂, in particular 1%, 2%, 3% 4%, 5%, 10% or 15% of PH₃ in N₂.

Preferably, the target contents C1 of dopant gas are between 0,0001% and 50%, preferably between 0.1% and 30%, the remainder being the carrier gas.

In order to demonstrate the effectiveness of a plant according to the invention, the production and delivery on site of a mixture comprising diborane (B₂H₆) as dopant gas in hydrogen as carrier gas were carried out. The dopant gas was composed of a premix of diborane in a proportion of 20% by volume diluted in hydrogen. The plant comprised a first feedback loop of PID type as described above and a second feedback loop.

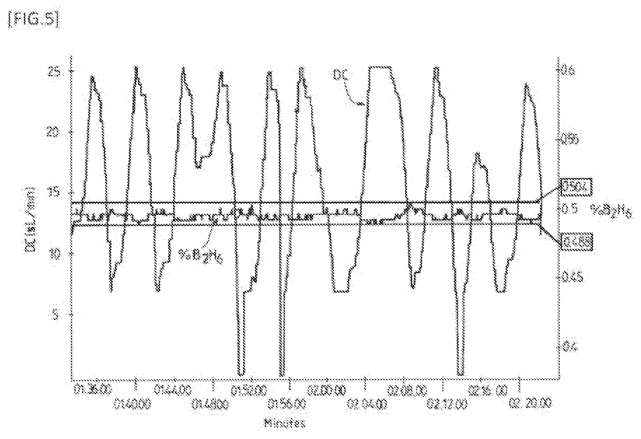

In a first test, corresponding to FIG. 4, the production of the mixture having contents of B₂H₆ that were increased stepwise was carried out, this being in order to show the accuracy and the resolution that can be obtained in the content of dopant gas. An accuracy of 0.005% (absolute %) was able to be achieved over the content of B₂H₆.

In a second step, corresponding to FIG. 5, a mixture was produced with a target content C1 of B₂H₆ of 0.5% (% by volume) and this content was measured during fluctuations in the consumption of the doping unit. FIG. 5 shows a recording of the gas mixture flow rate DC delivered by the delivery line with the B₂H₆ content which are measured during this recording.

A gas mixture flow rate DC that varies typically between 0 and 30 slim in was able to be produced with a stability of the B₂H₆ content that is characterized by a relative standard deviation of the order of 0.008% (absolute %) or 80 ppm as absolute value, i.e. 1.6% as relative value. The content measured was 0.494% on average. The horizontal lines indicate the minimum and maximum values attained by the B₂H₆ content during the recording.

It should be noted that the present description describes a gas mixture containing two constituents but that it can be transposed to any mixture having a greater number of constituents. For example, in the case of a ternary gas mixture, three sources each deliver a dopant gas, a carrier gas and a third gas. Flow regulator members 41, 42, 43 receive the order from the control unit 5 to regulate the flow of the dopant gas, carrier gas and third gas to respective flow rate setpoints D1, D2, D3. The mixer device is configured to deliver a mixture of flow rate DP equal to the sum of D1, D2, D3. The proportions of dopant gas, carrier gas and third gas relative to DP are determined as a function of at least two out of three target contents C1 C2, C3 of dopant gas, carrier gas and third gas respectively in the gas mixture. AH or some of the characteristics already described for a mixture containing two gases can be transposed to this mixture containing three or more gases.

It will be understood that many additional changes in the details, materials, steps and arrangement of parts, which have been herein described in order to explain the nature of the invention, may be made by those skilled in the art within the principle and scope of the invention as expressed in the appended claims. Thus, the present invention is not intended to be limited to the specific embodiments in the examples given above.

1. A plant for delivering a gas mixture suitable for and intended to be used in a silicon wafer doping unit, said plant comprising:
a source of a dopant gas (1),
a source of a carrier gas (2),
a mixer device (3) fluidically connected to the container of dopant gas (1) and to the source of carrier gas (2), said mixer device (3) being configured to produce, at an outlet (33), a gas mixture comprising the dopant gas and the carrier gas,
a first flow regulator member (41) and a second flow regulator member (42) which are configured to regulate respectively the flow of the dopant gas (1) and the flow of the carrier gas (2) flowing towards the mixer device (3) according to a first flow rate setpoint (D1) and a second flow rate setpoint (D2) defining, in operation, a production flow rate (DP) of the gas mixture at the outlet (33) of the mixer device (3),
a control unit (5) configured to control the first and second flow regulator members (41, 42) so as to adjust the first flow rate setpoint (D1) and the second flow rate setpoint (D2) in respective proportions relative to the production flow rate (DP), said respective proportions being determined as a function of at least one target content (C1, C2) of dopant gas (1) and/or carrier gas (2) in the gas mixture,
a buffer tank (7) connected by an outlet duct (23) to the outlet (33) of the mixer device (3) on the one hand and to a delivery line (6) on the other hand, the delivery line (6) being configured to deliver the gas mixture to a silicon wafer doping unit (10) with a consumption flow rate (DC) representative of a variable consumption of the gas mixture,
at least one measurement sensor (8) configured to measure a physical quantity, the variation of which is representative of a variation in the consumption flow rate (DC) delivered by the delivery line (6) and to provide a first measurement signal of said physical quantity,
the control unit (5) being connected to the measurement sensor (8) and configured to produce a first control signal from the first measurement signal, the flow regulator members (41, 42) being configured to adjust the first flow rate setpoint (D1) and the second flow rate setpoint (D2) in response to said first control signal.

2. The plant according to claim 1, further comprising
a first analysis unit (13) arranged downstream of the buffer tank (7) and configured to analyse at least one respective content of dopant gas (1) and/or carrier gas (2) in the gas mixture delivered by the supply line (6).

3. The plant according to claim 2, further comprising
a first sampling duct (36) connecting the first analysis unit (13) to the supply line (6) at a first sampling point (36a); and
a first return line (37) connecting the first analysis unit (13) to the supply line (6) at a first return point (37a), the return point (37a) being located downstream of the first sampling point (36a) on the supply line (6), a pressure-reducing valve (51) being mounted on the supply line (6) between the first sampling point (36a) and the first return point (37a), preferably the pressure-reducing valve (51) is mounted upstream of the measurement sensor (8).

4. The plant according to claim 3, further comprising
a second analysis unit (14) configured to measure at least one content of dopant gas (1) and/or carrier gas (2) in the gas mixture produced at the first outlet (33) of the mixer device (3) and to consequently provide at least a second measurement signal, the control unit (5) being connected to the second analysis unit (14) and configured to produce a second control signal from the second measurement signal and to modify the proportion of the first flow rate setpoint (D1) and/or the proportion of the second flow rate setpoint (D2) relative to the production flow rate (DP) in response to said second control signal.

5. The plant according to claim 4, further comprising
a second sampling duct (34) connecting the second analysis unit (14) to the outlet line (23) at a second sampling point (34a); and
a second return line (35) connecting the second analysis unit (14) to the outlet line (23) at a second return point (35a), the return point (35a) being located downstream of the second sampling point (34a) on the outlet line (23), a backpressure regulator (52) being mounted on the outlet line (23), between the second sampling point (34a) and the second return point (35a).

6. The plant according to claim 1, wherein the plant is configured to deliver a mixture having a content of dopant gas (1) of between 0.0001% and 50%.

7. The plant according to claim 1, wherein the source of dopant gas (1) contains germanium tetrahydride (GeH₄), phosphine (PH₃), arsine (AsH₃) and/or diborane (B₂H₆) and the source of carrier gas (2) contains hydrogen (H₂), nitrogen (N₂) and/or argon (Ar).

8. The plant according to claim 1, wherein the source of dopant gas (1) contains a gas premix formed of dopant gas (1) and carrier gas (2).

9. The plant according to claim 1, further comprising a first feedback loop from the first and second flow rate setpoints (D1, D2) to the first measurement signal provided by the measurement sensor (8), said first loop comprising:
a first comparator (11A) arranged within the control unit (5) and configured to produce at least a first error signal from the first measurement signal,
a first corrector (12A) arranged within the control unit (5), in particular of proportional, integral and derivative (PID) type, and configured to produce the first control signal from the first error signal,
actuators of the first and second flow regulator members (41, 42) which are connected to the first corrector (12A) and configured to receive the first control signal and move the first and second flow regulator members (41, 42) into respective positions in which the first flow rate setpoint (D1) and the second flow rate setpoint (D2) comply with the first control signal.

10. The plant according to claim 1, further comprising a second feedback loop from the respective proportions of the first flow rate setpoint (D1) and/or the second flow rate setpoint (D2) relative to the production flow rate (DP) to the second measurement signal provided by the second analysis unit (14), the second feedback loop comprising:
a second comparator (11B) arranged within the control unit (5) and configured to produce at least a second error signal from a comparison of the second measurement signal with at least one parameter chosen from: a target content (C1) of the dopant gas (1), a target content (C2) of the carrier gas (2),
a second corrector (12B) arranged within the control unit (5), in particular of proportional, integral and derivative (PID) type, and configured to produce the second control signal from the second error signal; and
actuators of the first and second flow regulator members (41, 42) which are connected to the second corrector (12B) and configured to move the first and/or second flow regulator members (41, 42) into respective positions in which the proportions of the first flow rate setpoint (D1) and/or second flow rate setpoint (D2) relative to the production flow rate (DP) comply with the second control signal.

11. The plant according to claim 1, wherein the measurement sensor (8) comprises a flow sensor or flowmeter configured to measure the consumption flow rate (DC).

12. The plant according to claim 11, wherein the first comparator (11A) is configured to produce at least a first error signal representative of a variation in the consumption flow rate (DC) and the first corrector (12A) is configured to produce a first control signal controlling a movement of the first and second flow regulator members (41, 42) so that the first and second flow rate setpoints (D1, D2) vary in the same direction as that of the variation in the flow rate (DC).

13. The plant according to claim 1, wherein the measurement sensor (8) comprises a pressure sensor configured to measure the pressure prevailing in the buffer tank (7).

14. The plant according to claim 13, wherein the first comparator (11A) is configured to produce a first error signal representative of a variation in the pressure in the buffer tank (7) and the first corrector (12A) is configured to produce at least a first control signal controlling a movement of the first and second flow regulator members (41, 42) so that the first and second flow rate setpoints (D1, D2) vary in the opposite direction to that of the variation in the pressure.

15. An assembly comprising a silicon wafer doping unit comprising a furnace equipped with a chamber associated with heating means and a support arranged in said chamber on which wafers are installed, the furnace comprising means for introducing a mixture of dopant gas (1) and of carrier gas (2) into the chamber, wherein the assembly further comprises a plant according to one of claims 1 to 14, said introduction means being fluidically connected to the supply line (6) of said plant.

16. The plant according to claim 1, wherein the plant is configured to deliver a mixture having a content of dopant gas (1) of between 0.05% and 30% (% by volume).

17. The plant according to claim 1, wherein the source of dopant gas (1) contains germanium tetrahydride (GeH₄), phosphine (PH₃), arsine (AsH₃) and/or diborane (B₂H₆) or the source of carrier gas (2) contains hydrogen (H₂), nitrogen (N₂) and/or argon (Ar).
